(19) United States
(12) Patent Application Publication
(10) Pub. No.: US 2026/0147066 A1
(43) Pub. Date: May 28, 2026

(54) TERMINAL POSITION DETECTION DEVICE

(71) Applicant: TE Connectivity Solutions GmbH, Schaffhausen (CH)

(72) Inventors: Jose Manuel ROSAS GARCIA, Empalme (MX); Juan Carlos ROMERO, Hermosillo (MX); Yiyang LIEW, Winston Salem, NC (US)

(21) Appl. No.: 19/388,680

(22) Filed: Nov. 13, 2025

Related U.S. Application Data
(60) Provisional application No. 63/723,832, filed on Nov. 22, 2024.

(51) Int. Cl. G01R 31/67

(52) U.S. Cl. CPC G01R 31/67

(57) ABSTRACT

A terminal position detection device for detecting incorrect positioning of a terminal in a connector includes a device body including a connector chamber configured to receive the connector. The terminal position detection device includes a terminal sensor at the connector chamber. The terminal sensor configured to be operably coupled to the connector in the connector chamber. The terminal sensor operable to detect presence or absence of the terminal in the connector by inductive sensing through a housing of the connector for determining proper or incorrect positioning of the terminal in the connector.

### CROSS REFERENCE TO RELATED APPLICATIONS

This application claims priority to U.S. Application No. 63/723,832, filed 22 Nov. 2024, the subject matter of which is herein incorporated by reference in its entirety.

### BACKGROUND OF THE INVENTION

The subject matter herein relates generally to inspection methods and devices for proper mating of electrical connectors.

Electrical connectors are widely used in electronic systems to establish reliable electrical interconnections between components, subassemblies, and devices. In many applications, proper mating between connector halves is critical to ensure consistent electrical performance and product reliability. Improperly seated or misaligned terminals within the connector cavities can lead to intermittent electrical contact, high contact resistance, or even open circuits, ultimately resulting in product malfunction or failure in the field.

Traditional methods for detecting proper mating and terminal positioning in electrical connectors have proven inadequate for use in high-volume production environments. Common electrical testing techniques, such as resistance or continuity checks, rely on the presence of an electrical path between mating terminals. However, these methods are ineffective when an incorrectly positioned terminal still establishes incidental or partial contact with the mating terminal. In such cases, a continuity or resistance test may indicate an acceptable electrical connection even though the mechanical engagement and positional alignment of the terminal are incorrect.

Other verification methods, such as mate force testing, depend on monitoring the insertion or mating force between connector pairs. While such force measurements may reveal gross misalignment or interference, they lack the sensitivity to detect subtle variations in terminal position or partial engagement within the connector cavity. Moreover, mate force testing can be inconsistent due to tolerances in connector housing geometry, terminal retention features, and operator technique.

Destructive inspection methods, including sectioning or disassembly of connectors, provide a direct means of evaluating terminal positioning but are impractical for production testing. Such approaches are time-consuming, costly, and result in the loss of otherwise functional assemblies. In addition, destructive methods cannot be applied to every production unit, limiting their usefulness for process control or quality assurance.

A further challenge in detecting improper terminal seating arises from the lack of visual or physical access to the terminals once the connector pair is mated. The terminals are typically enclosed within mating housings, making it impossible to inspect terminal position or engagement visually or mechanically without damaging the connector. As a result, existing inspection and electrical test methods are unable to detect subtle misalignment conditions that may compromise long-term reliability.

Accordingly, there exists a need for a non-destructive and non-invasive system for detecting improper mating or terminal positioning in electrical connectors. Such a system should be capable of identifying misaligned or insufficiently seated terminals that may not be detectable through electrical continuity or resistance checks alone. The system should enable rapid, accurate, and repeatable detection of improper mating conditions in a production environment without compromising connector integrity, thereby saving time, reducing cost, and improving overall product quality.

### BRIEF DESCRIPTION OF THE INVENTION

In an embodiment, a terminal position detection device for detecting incorrect positioning of a terminal in a connector is provided. The terminal position detection device includes a device body including a connector chamber configured to receive the connector. The terminal position detection device includes a terminal sensor at the connector chamber. The terminal sensor configured to be operably coupled to the connector in the connector chamber. The terminal sensor operable to detect presence or absence of the terminal in the connector by inductive sensing through a housing of the connector for determining proper or incorrect positioning of the terminal in the connector.

In another embodiment, a terminal position detection device for detecting incorrect positioning of a terminal in a connector is provided. The terminal position detection device includes a device body including a connector chamber configured to receive the connector. The terminal position detection device includes a connector location sensor in the connector chamber configured to interface with the connector to detect proper positioning of the connector in the connector chamber. The terminal position detection device includes a terminal sensor at the connector chamber. The terminal sensor configured to be operably coupled to the connector in the connector chamber. The terminal sensor operable to detect presence or absence of the terminal in the connector by inductive sensing through a housing of the connector for determining proper or incorrect positioning of the terminal in the connector.

In a further embodiment, a terminal position detection device for detecting incorrect positioning of a terminal in a connector is provided. The terminal position detection device includes a device body including a connector chamber configured to receive the connector. The terminal position detection device includes a terminal sensor at the connector chamber. The terminal sensor configured to be operably coupled to the connector in the connector chamber. The terminal sensor operable to detect presence or absence of the terminal in the connector by inductive sensing through a housing of the connector for determining proper or incorrect positioning of the terminal in the connector. The terminal position detection device includes a visual indicator coupled to the device body. The visual indicator operably coupled to the terminal sensor to provide a visual indication to the user of a status of the terminal sensor.

### BRIEF DESCRIPTION OF THE DRAWINGS

FIG. 1 illustrates a terminal position detection device in accordance with an exemplary embodiment for detecting incorrect positioning of a terminal in a connector (also shown in FIG. 2).

FIG. 2 illustrates the mated pair including the connector and a mating connector in a mated condition in accordance with an exemplary embodiment.

FIG. 3 is an end view of the terminal position detection device in accordance with an exemplary embodiment.

FIG. 4 is a side perspective view of a portion of the terminal position detection device showing the connector in accordance with an exemplary embodiment.

FIG. 5 is a sectional view of the terminal position detection device sensing an improperly positioned terminal in the mated pair in accordance with an exemplary embodiment.

FIG. 6 is a sectional view of the terminal position detection device sensing a properly positioned terminal in the mated pair in accordance with an exemplary embodiment.

### DETAILED DESCRIPTION OF THE INVENTION

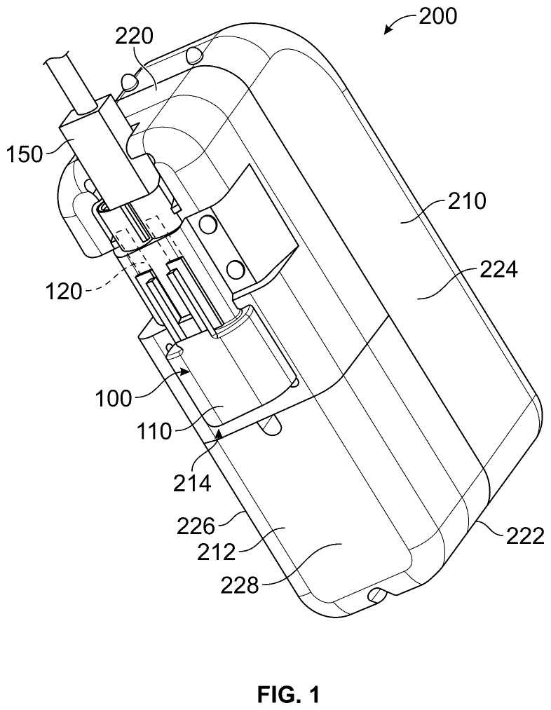

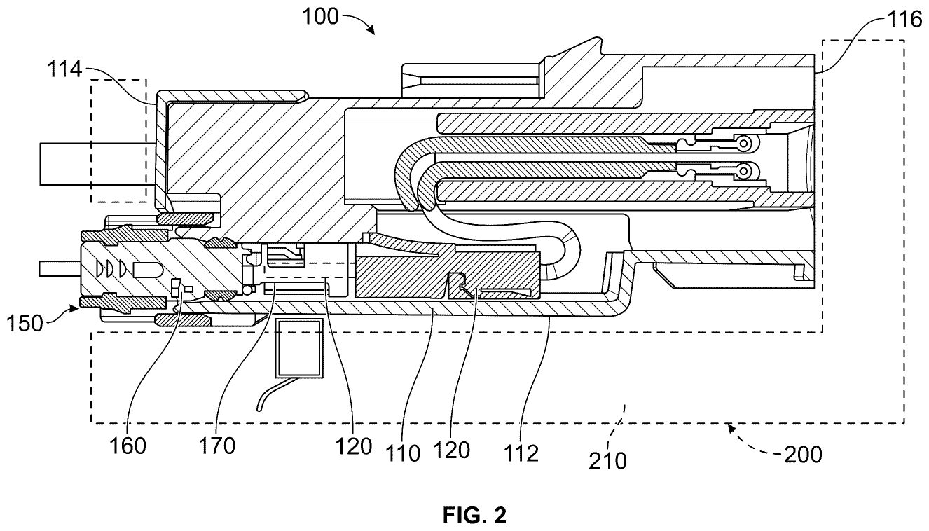

FIG. 1 illustrates a terminal position detection device 200 in accordance with an exemplary embodiment for detecting incorrect positioning of a terminal 120 in a connector 100 (also shown in FIG. 2). The terminal position detection device 200 is configured to detect the position of the terminal 120 in the interior of a housing 110 of the connector 100. In various embodiments, the terminal position detection device 200 is used for determining a connection status of a mated pair without unmating the connectors of the mated pair. For example, the terminal position detection device 200 is configured to detect a position of the terminal 120 inside the connector enclosure of the mated pair without unmating the connection. The terminal position detection device 200 uses a nondestructive and noninvasive sensing means for detecting whether or not the terminal is in the correct position or incorrect position inside the connector 100 and/or within the mated pair. As such, the terminal position detection device 200 eliminates the risk of compromising the product integrity by avoiding invasive methods detection. The terminal position detection device 200 assures proper positioning of the terminal in the connector 100 and/or the mated pair after assembly and prior to installation of the mated pair into the system, such as into a vehicle.

With additional reference to FIG. 2, which illustrates the mated pair including the connector 100 and a mating connector 150 in a mated condition. The connector 100 includes the housing 110 holding one or more of the terminals 120. The housing 110 includes housing walls 112 that form terminal cavities that hold the terminals 120. The housing 110 extends between a first end 114 and a second end 116. The mating connector 150 is configured to be coupled to the housing 110 at the first end 114. In various embodiments, the second end 116 forms a mating interface for mating with another electrical connector.

The mating connector 150 includes a housing 160 holding one or more terminals 170. The mating connector 150 is coupled to the first end 114 of the connector 100 to form the mated pair. In various embodiments, the connector 100 is a receptacle connector and the mating connector 150 is a plug connector to be plugged into the receptacle connector. In alternative embodiments, the connector 100 is a plug connector and the mating connector 150 is a receptacle connector. The connectors 100, 150 may be power connectors and/or data connectors. The terminals 120, 170 may be power terminals, signal terminal terminals, or other types of terminals.

With reference back to FIG. 1, the terminal position detection device 200 includes a device body 210 having walls 212 forming a connector chamber 214 configured to receive the connector 100. In an exemplary embodiment, the terminal position detection device 200 is a handheld device configured to be held by the operator during testing of the connection status of the mated pair. In alternative embodiments, the terminal position detection device 200 may be part of an assembly machine or testing machine that receives the mated pair for testing after assembly. The terminal position detection device 200 is operated to test the connection status and determine whether or not the terminal 120 is in the correct position or incorrect position inside the connector 100 and properly mated with the mating terminal 170 of the mating connector 150.

In an exemplary embodiment, the device body 210 of the terminal position detection device 200 includes a top 220, a bottom, 222, a first side 224, and a second side 226. The device body 210 includes a receiving end 228 that receives the connector 100. The connector chamber 214 is provided at the receiving end 228. For example, the connector chamber 214 is open at the receiving end 228 for loading the connector 100 into the connector chamber 214. The connector chamber 214 may be located proximate to the top 220. Optionally, a portion of the connector chamber 214 may be open at the top 220 to allow the connector 100 and/or the mating connector 150 to pass therethrough and extend from the top 220. The connector chamber 214 is located between the first and second sides 224, 226.

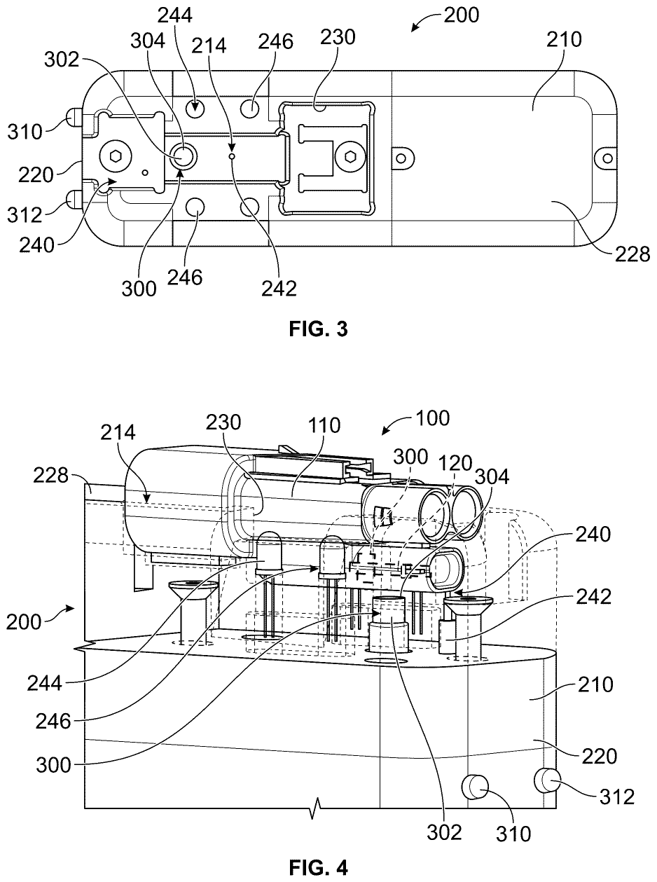

FIG. 3 is an end view of the terminal position detection device 200 in accordance with an exemplary embodiment. FIG. 4 is a side perspective view of a portion of the terminal position detection device 200 showing the connector 100. The terminal position detection device 200 includes the device body 210 and the connector chamber 214 that is configured to receive the connector 100 (shown in FIG. 4).

In an exemplary embodiment, the terminal position detection device 200 includes a terminal sensor 300 at the connector chamber 214. The terminal sensor 300 is configured to be operably coupled to the connector 100 in the connector chamber 214. The terminal sensor 300 is operable to detect presence or absence of the terminal 120 in the connector 100 by inductive sensing through the housing 110 of the connector 100 for determining proper or incorrect positioning of the terminal 120 in the connector 100. In an exemplary embodiment, the terminal sensor 300 is an inductive sensor.

The connector chamber 214 of the device body 210 receives the connector 100 therein, such as through the receiving end 228. The device body 210 includes locating features 230 that locate the connector 100 in the connector chamber 214. The locating features 230 may include walls, tabs, protrusions, pins, posts, slots, grooves, channels, or other types of locating features to interface with and position the connector 100 in the connector chamber 214.

In an exemplary embodiment, the terminal position detection device 200 includes a connector location sensor 240 in the connector chamber 214 configured to interface with the connector 100 to detect proper positioning of the connector 100 in the connector chamber 214. In an exemplary embodiment, the connector location sensor 240 includes one or more sense pins 242 configured to interface with the housing 110. In various embodiments, the connector location sensor 240 includes multiple sense pins 242 to interface with different portions of the connector 100 to assure proper positioning of the connector 100 in the connector chamber 214.

In an exemplary embodiment, the terminal position detection device 200 includes a visual indicator 244 operably coupled to the connector location sensor 240. In the illustrated embodiment, the visual indicator 244 is located at the receiving end 228, such as in the connector chamber 214. Other locations are possible in alternative embodiments. The visual indicator 244 provides a visual indication to the user of a status of the connector location sensor 240. For example, the visual indicator 244 may provide a visual indication corresponding to the positioning of the connector 100 in the connector chamber 214. The visual indicator 244 may provide one status indication when the connector 100 is properly positioned and a different status indication when the connector 100 is not properly positioned. The visual indicator 244 may include one or more light emitting diodes 246 or other indicators. For example, the visual indicator 244 may include a green LED operated when the connector 100 is properly positioned and a red LED operated when the connector 100 is improperly positioned. The visual indicator 244 may include a display. Other types of indicators may be used such as audible indicators, tactile indicators, and the like to indicate to the user the position of the connector.

In an exemplary embodiment, the terminal sensor 300 is positioned in the device body 210 at the connector chamber 214. A portion of the terminal sensor 300 may extend into the connector chamber 214 for operating on the connector 100 when the connector 100 is in the connector chamber 214. In an exemplary embodiment, the terminal sensor 300 is configured to be aligned with a mating interface of the connector 100 to sense the terminal 120 at the mating interface. In an exemplary embodiment, the terminal sensor 300 may interface directly with the connector 100, such as with the housing 110. For example, the terminal sensor 300 includes a sensor interface 304 configured to interface with the housing 110 of the connector 100.

In an exemplary embodiment, the terminal sensor 300 includes an inductive sensor 302. The inductive sensor 302 creates an electromagnetic field that is emitted into the connector 100. The electromagnetic field is disrupted by the presence of a metallic object, such as the terminal 120. When the terminal 120 enters the inductive sensors field, eddy currents are induced in the target, which in turn cause a change in the terminal sensor 300 oscillating circuit. This change is detected by internal circuitry of the terminal sensor 300, which triggers a signal or indicator to show that the terminal 120 has been detected. The inductive sensor 302 is configured to operate through the plastic material of the housing 110 and thus can detect the presence of the terminal 120 in the mated pair without unmating the connectors.

In an exemplary embodiment, the terminal position detection device 200 includes a visual indicator 310 operably coupled to the terminal sensor 300. In the illustrated embodiment, the visual indicator is located at the top 220. Other locations are possible in alternative embodiments. The visual indicator 310 provides a visual indication to the user of a status of the terminal sensor 300. For example, the visual indicator 310 may provide a visual indication corresponding to the absence of the terminal 120 or the presence of the terminal 120 in a predetermined position within the connector 100 corresponding to proper or improper positioning of the terminal 120 within the mated pair. The visual indicator 310 may provide one status indication when the terminal 120 is not detected and a different status indication when the terminal 120 is detected. The visual indicator 310 may include one or more light emitting diodes 312 or other indicators. For example, the visual indicator 310 may include a green LED operated when the presence of the terminal 120 is not detected and a red LED operated when the presence of the terminal 120 is detected. The visual indicator 310 may include a display. Other types of indicators may be used such as audible indicators, tactile indicators, and the like to indicate to the user the /sence/ presence of the terminal 120 corresponding to proper/improper mating of the mated pair.

In an exemplary embodiment, the terminal position detection device 200 includes multiple terminal sensors 300 in the connector chamber 214. The terminal position detection device 200 may include two or more of the terminal sensors 300. The various terminal sensors 300 may be configured to operably detect presence or absence of different terminals 120 in the connector 100. For example, the terminal sensors 300 may be aligned with different terminal channels to sense locations (presence/absence) of the terminals 120. The various terminal sensors 300 may be configured to operably detect presence or absence of the same terminal 120, but from different sensing directions or in different locations within the housing 110. For example, the terminal sensors 300 may be positioned at different locations relative to the terminal 120 to sense presence/absence of the terminal 120 at different areas of the housing 110. For example, a first terminal sensor 300 may be configured to interface with a first housing wall (for example, bottom wall) of the housing 110 and a second terminal sensor 300 may be configured to interface with a second housing wall (for example, side wall) of the housing 110 different from the first housing wall.

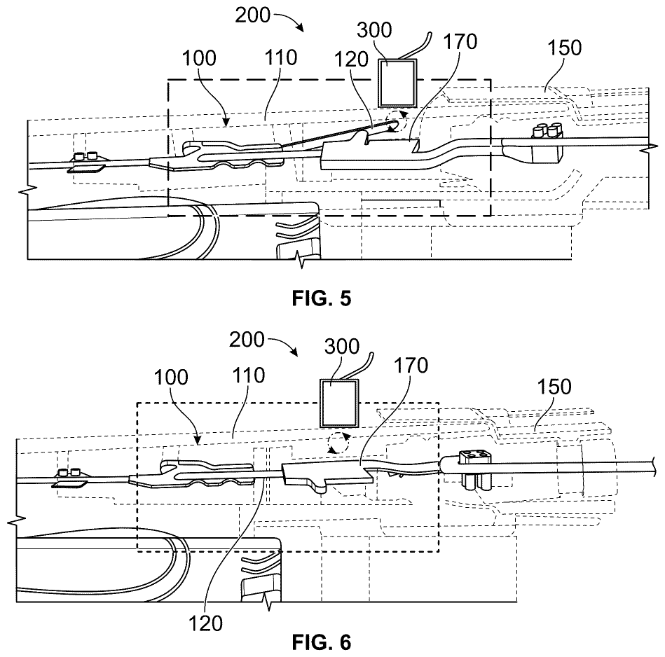

FIG. 5 is a sectional view of the terminal position detection device 200 sensing an improperly positioned terminal 120 in the mated pair. FIG. 6 is a sectional view of the terminal position detection device 200 sensing a properly positioned terminal 120 in the mated pair. The terminal sensor 300 is positioned in close proximity to the connector 100, such as adjacent the exterior of the housing 110. The terminal sensor 300 uses inductive sensing to create an electromagnetic field emitted into the connector 100 for sensing the terminal 120. The electromagnetic field is disrupted by the presence of the terminal 120. For example, when the terminal 120 enters the inductive sensors field, eddy currents are induced, which in turn cause a change in the terminal sensor 300 oscillating circuit. This change is detected by internal circuitry of the terminal sensor 300, which triggers a signal or indicator to show that the terminal 120 has been detected. The electromagnetic field operates through the plastic material of the housing 110 and thus can detect the presence of the terminal 120 in the mated pair without unmating the connectors.

During mating of the connectors 100, 150, the terminal 120 is configured to be mated with the mating terminal 170. In the illustrated embodiment, the terminal 120 is a blade terminal or pin terminal and the mating terminal 170 is a socket terminal that receives the blade terminal or pin terminal. In some situations, the terminal 120 may be improperly mated. For example, the terminals 120, 170 may not be properly aligned and the terminal 120 may be bent outward, outside of the socket. While the terminal 120 may be physically touching the mating terminal 170, thus creating an electrical connection and thus unable to detect the improper mating through electrical continuity testing, the connection may eventually fail and de-mate, such as from vibration over time. The terminal sensor 300 is able to detect the presence of the terminal 120 when the terminal 120 is deflected outward into an area of the connector 100 in which the terminal is not designed to be located. If the terminal 120 is detected by the terminal sensor 300 (FIG. 5), the terminal position detection device 200 is able to indicate to the operator that the connectors 100, 150 are improperly mated and that the parts should be scrapped or re-assembled properly. However, if the terminal sensor 300 does not detect the presence of the terminal 120 (FIG. 6), then the terminal position detection device 200 may indicate to the operator that the connectors 100, 150 are properly mated.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. § 112(f), unless and until such claim limitations expressly use the phrase “means for” followed by a statement of function void of further structure.

What is claimed is:

1. A terminal position detection device for detecting incorrect positioning of a terminal in a connector, the terminal position detection device comprising:
a device body including a connector chamber configured to receive the connector; and
a terminal sensor at the connector chamber, the terminal sensor configured to be operably coupled to the connector in the connector chamber, the terminal sensor operable to detect presence or absence of the terminal in the connector by inductive sensing through a housing of the connector for determining proper or incorrect positioning of the terminal in the connector.

2. The terminal position detection device of claim 1, wherein the terminal sensor is an inductive sensor.

3. The terminal position detection device of claim 1, wherein the terminal sensor is configured to be aligned with a mating interface of the connector.

4. The terminal position detection device of claim 1, wherein the terminal sensor is held by the device body in the connector chamber.

5. The terminal position detection device of claim 1, wherein the terminal sensor includes a sensor interface configured to interface with the housing of the connector.

6. The terminal position detection device of claim 1, further comprising a visual indicator operably coupled to the terminal sensor to provide a visual indication to the user of a status of the terminal sensor.

7. The terminal position detection device of claim 1, further comprising a connector location sensor in the connector chamber configured to interface with the connector to detect proper positioning of the connector in the connector chamber.

8. The terminal position detection device of claim 7, wherein the connector location sensor includes one or more sense pins configured to interface with the housing.

9. The terminal position detection device of claim 7, further comprising a visual indicator operably coupled to the connector location sensor to provide a visual indication to the user of a status of the connector location sensor.

10. The terminal position detection device of claim 1, wherein the terminal sensor is a first terminal sensor, the terminal position detection device further comprising a second terminal sensor at the connector chamber.

11. The terminal position detection device of claim 10, wherein the second terminal sensor is configured to operably detect presence or absence of a second terminal in the connector by inductive sensing through the housing of the connector for determining proper or incorrect positioning of the second terminal in the connector.

12. The terminal position detection device of claim 10, wherein the second terminal sensor is configured to operably detect presence or absence of the terminal in the connector from a different sensing direction through the housing of the connector for determining proper or incorrect positioning of the second terminal in the connector.

13. The terminal position detection device of claim 12, wherein the terminal sensor senses in a first sensing direction and the second terminal sensor senses in a second sensing direction different from the first sensing direction.

14. The terminal position detection device of claim 12, wherein the terminal sensor is configured to interface with a first housing wall of the housing and the second terminal sensor is configured to interface with a second housing wall of the housing different from the first housing wall.

15. A terminal position detection device for detecting incorrect positioning of a terminal in a connector, the terminal position detection device comprising:
a device body including a connector chamber configured to receive the connector;
a connector location sensor in the connector chamber configured to interface with the connector to detect proper positioning of the connector in the connector chamber; and
a terminal sensor at the connector chamber, the terminal sensor configured to be operably coupled to the connector in the connector chamber, the terminal sensor operable to detect presence or absence of the terminal in the connector by inductive sensing through a housing of the connector for determining proper or incorrect positioning of the terminal in the connector.

16. The terminal position detection device of claim 15, wherein the terminal sensor is configured to be aligned with the mating interface of the connector.

17. The terminal position detection device of claim 15, wherein the terminal sensor includes a sensor interface configured to interface with the housing of the connector.

18. The terminal position detection device of claim 15, further comprising a visual indicator operably coupled to the terminal sensor to provide a visual indication to the user of a status of the terminal sensor.

19. The terminal position detection device of claim 15, wherein the terminal sensor is a first terminal sensor, the terminal position detection device further comprising a second terminal sensor at the connector chamber.

20. A terminal position detection device for detecting incorrect positioning of a terminal in a connector, the terminal position detection device comprising:
a device body including a connector chamber configured to receive the connector;
a terminal sensor at the connector chamber, the terminal sensor configured to be operably coupled to the connector in the connector chamber, the terminal sensor operable to detect presence or absence of the terminal in the connector by inductive sensing through a housing of the connector for determining proper or incorrect positioning of the terminal in the connector; and
a visual indicator coupled to the device body, the visual indicator operably coupled to the terminal sensor to provide a visual indication to the user of a status of the terminal sensor.
